(19) United States
(12) Patent Application Publication
(10) Pub. No.: US 2013/0025922 A1
(43) Pub. Date: Jan. 31, 2013

(54) BONDING ENTITIES TO CONJOINED STRIPS OF CONDUCTIVE MATERIAL

(71) Applicant: Karl S. Weibezahn, Corvallis, OR (US)

(72) Inventor: Karl S. Weibezahn, Corvallis, OR (US)

(21) Appl. No.: 13/193,858

(22) Filed: Jul. 29, 2011

(51) Int. Cl. H05K 1/18; H05K 3/34

(52) U.S. Cl. 174/260; 29/840

(57) ABSTRACT

Methods and apparatus are provided for mass production of electronic devices. Rows of perforation are formed across a sheet of conductive material such that plural conjoined strips are defined. Respective electronic entities are soldered to each of the conjoined strips. The strips are separated by severing the perforations such that plural discrete electronic devices are defined. Solar panels, electronic circuits and other apparatus can be formed in this way.

### GOVERNMENTAL RIGHTS IN THE INVENTION

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Securing electronic devices and other entities to conductive circuit pathways is well known. However, some electronic devices lack extension wires, leads, or protrusions for use in a soldering process. Adding such leads for the sole purpose of solder bonding is costly and time consuming. The present teachings address the foregoing and other concerns.

### BRIEF DESCRIPTION OF THE DRAWINGS

The present embodiments will now be described, by way of example, with reference to the accompanying drawings, in which:

FIG. 1A is an isometric-like diagram depicting an exploded view of a sequence for forming devices according to one example;

FIG. 1B is an isometric-like diagram in accordance with FIG. 1A;

FIG. 1C is an isometric-like diagram in accordance with FIG. 1B;

FIG. 1D is an isometric-like diagram in accordance with FIG. 1C;

FIG. 1E is an isometric-like diagram depicting devices formed in accordance with FIGS. 1A-1D;

FIG. 2A is an isometric-like diagram depicting an exploded view of a sequence for forming devices according to another example;

FIG. 2B is an isometric-like diagram depicting devices formed in accordance with FIG. 2A;

FIG. 3A is a flow diagram depicting a first portion of a method according to one example;

FIG. 3B is a flow diagram depicting a second portion of the method of FIG. 3A.

### DETAILED DESCRIPTION

### Introduction

Methods and apparatus are provided for mass-production of electronic devices. Rows of perforation are formed across a sheet or ribbon of electrically conductive material such that plural conjoined strips are defined. In some examples, apertures are formed through the conductive material as well. Respective electronic entities are soldered to each of the conjoined strips. At least some of the electronic entities are in overlapping alignment with a respective aperture in applicable examples.

The strips are separated by severing the perforations so that plural discrete electronic devices are defined. Each discrete electronic device can include one or more electronic entities and one or more respective strips of conductive material. Solar panels, electronic circuits and other apparatus can be formed in this way.

In one example, a method includes forming parallel rows of perforations in an electrically conductive material such that a plurality of conjoined strips of the material is defined. The method also includes forming an aperture through each of the conjoined strips of the material. The method additionally includes providing a solder paste within each of the apertures. The method also includes disposing a respective entity in overlapping contacting relationship with each of the apertures. The method further includes electromechanically bonding the entities to the respective conjoined strips of the material by way of the solder paste.

In another example, a method of forming electronic devices includes forming one or more perforation lines across a sheet of conductive material so as to define a plurality of conjoined strips. The method also includes bonding one or more electronic entities to each of the conjoined strips by way of soldering. The method further includes separating the conjoined strips by way of the perforation lines to define a plurality of discrete electronic devices.

In still another example, an apparatus includes a plurality of like electronic devices, each including one or more electronic entities. Each electronic device also includes at least one electrically conductive strip of material bonded to the electronic entities there of. Each electrically conductive strip of material is defined by severed perforations along at least one edge.

### First Illustrative Formation

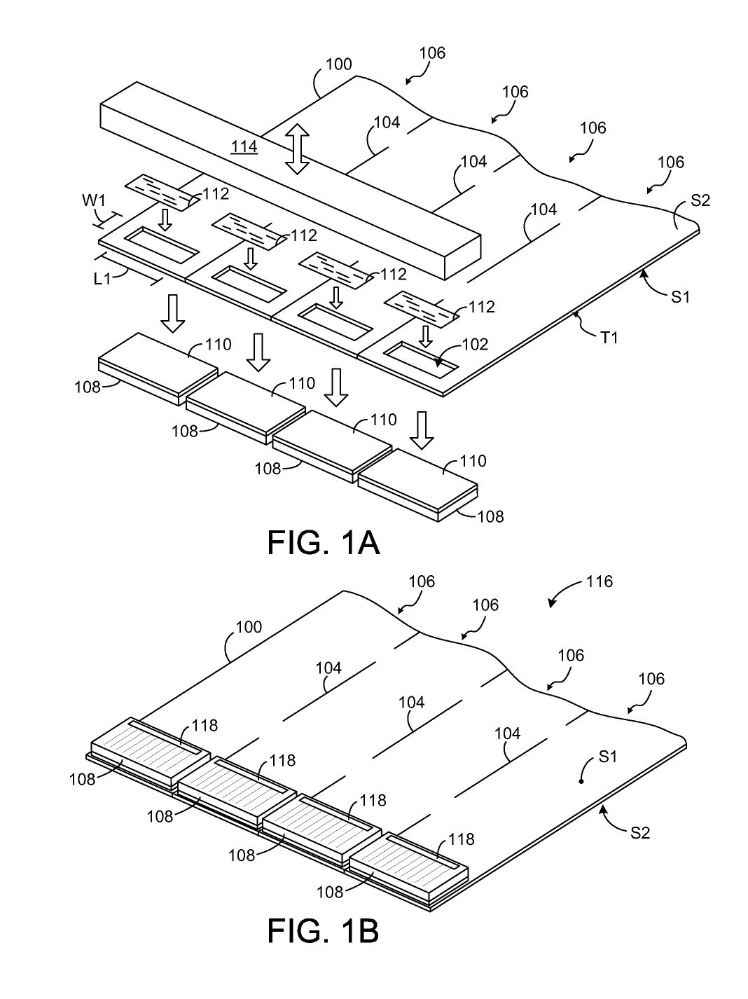

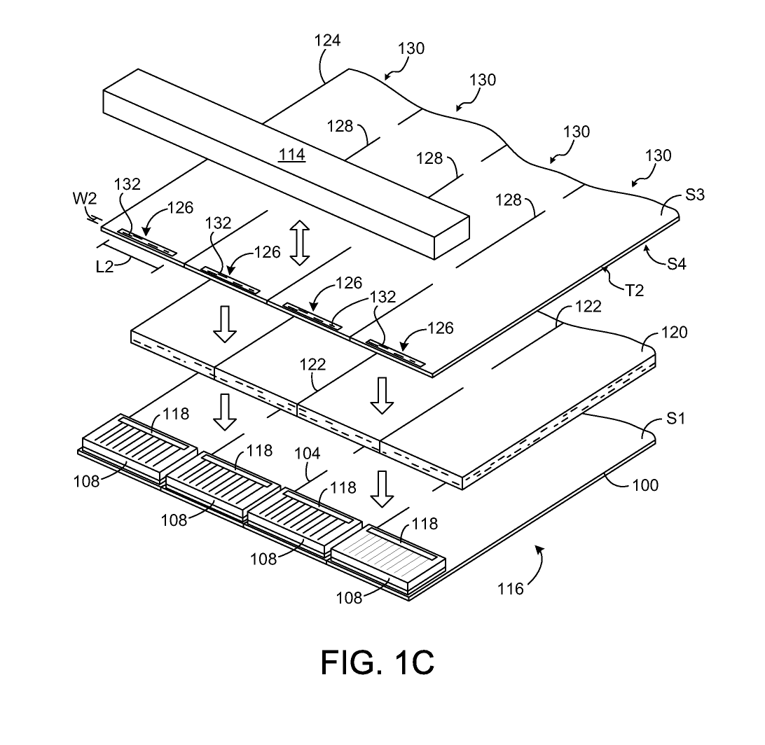

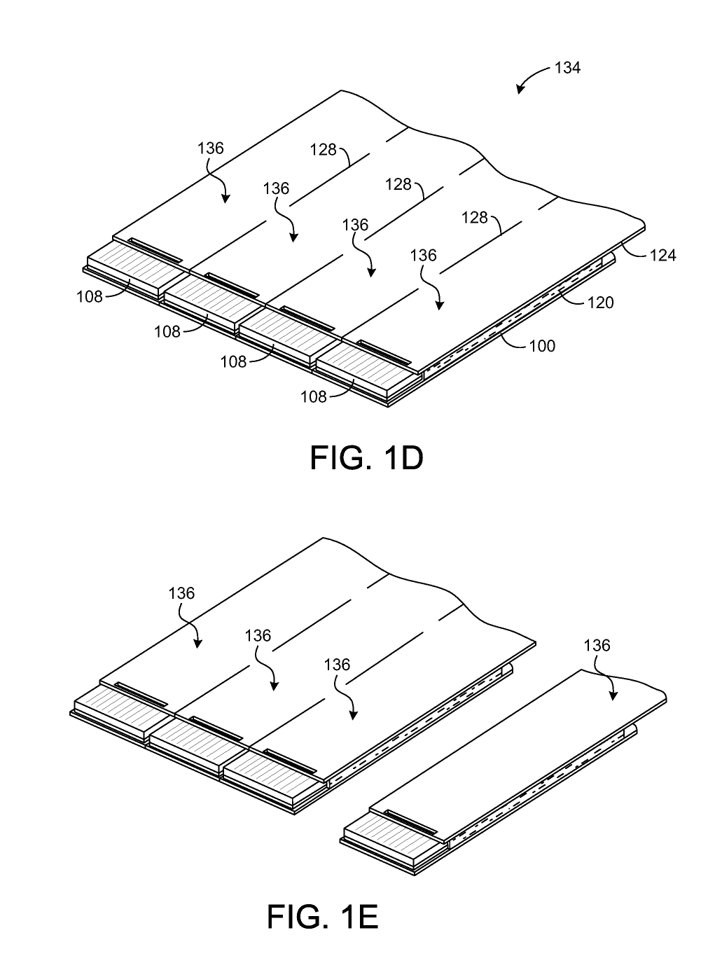

Reference is now directed to FIGS. 1A-1E, which collectively depict a sequence for forming discrete electronic devices 136. The sequence and the resulting electronic devices 136 is/are illustrative and non-limiting with respect to the present teachings. Thus, other apparatuses, devices can be configured and/or formed by way of other sequences in accordance with the present teachings.

FIG. 1A depicts a sheet of conductive material (material) 100. The material 100 can be defined by any suitable, solder-bondable material such as, for non-limiting example, copper, silver, brass, tin, and so on. Additionally, materials plated in solder-bondable materials such as gold or others can also be used. In one example, the material 100 is defined by copper sheet metal having a uniform thickness “T1” of about 0.005 inches. Other materials, having other respective dimensions and form factors (e.g., plates, sheets, ribbons, blocks, and so on), can also be used. The material 100 is defined by a first side surface “S1” and a second, opposite side surface “S2”.

The material 100 defines a plurality of through apertures 102. That is, a plurality of through apertures 102 has been formed in the material 102 by way of, without limitation, machine milling, machine punching, laser cutting, water-jet cutting, or other suitable means. Each through aperture (aperture) 102 is defined by a rectangular plan form having a length dimension “L1” and a width dimension “W1”. Other apertures having other suitable plan forms (e.g., oval, elliptical, circular, triangular, and so on) or cross-sectional profiles can also be used.

The material 100 also includes respective rows of perforations or “slits” 104 formed therein such that a plurality conjoined strips 106 of the material 100 are defined. The material 100 is still considered a singular entity as depicted in FIG. 1A by virtue of the intact state of the perforations 104. The perforations 104 can be formed or defined by, without limitation, laser ablation, water-jet cutting, slicing, and so on. Other suitable formation techniques can also be used. In one example, the respective rows of perforations 104 are parallel to each and equally spaced such that the strips 106 are of equal size and aspect. Other configurations or perforation patterns can also be defined and used.

A plurality of electronic entities 108 each include a solderable surface feature 110. Each electronic entity 108 can be respectively defined by a passive or active electronic component such as a resistor, a capacitor, a transistor, an integrated circuit, a diode, a light-emitting diode (LED), and so on. Other entities 108 can also be used. In turn, the solderable surface feature 110 of each entity 108 can be defined by gold, copper, silver, or another suitable solder-bondable material. In one example, each of the entities 108 is defined by a photovoltaic cell having a solderable surface feature 110 formed of gold-plated nickel. Other examples can also be used.

The material 100 is brought into contact with the electronic entities 108 such that each entity 108 overlaps a respective one of the apertures 102. That is, the entities 108 are disposed in one-to-one correspondence with the conjoined strips 106, in overlapping alignment with the respective aperture 102. The solderable surface feature 110 of each entity 108 is therefore in contact with the side S1 of the material 100.

A quantity of solder paste 112 is introduced or provided into each of the apertures 102 and in resting contact with the corresponding solderable surface feature 110. A heated bar, referred to herein as a “hot bar” 114, is brought into contact with side S2 of the material 100, coincident with the respective apertures 102. In one example, the hot bar 114 is controlled in accordance with time-and-temperature profile information as provided by the vendor or source of the solder paste 112.

During contact by the hot bar 114 the respective quantities of solder paste 112 melt and reflow by way of capillary action into wetted contact with the respective solderable surface feature 110 in contact therewith. The hot bar 114 is then drawn away, allowing the quantities of solder paste 112 to cool and solidify. Each of the entities 108 is thus electromechanically bonded to a corresponding one of the conjoined strips 106 of the material 100. In another example, the solder paste 112 begins or is allowed to cool during hot bar contact in accordance with a controlled temperature rate there of.

It is noted that each of the entities 108—including the solderable surface feature 110 of each—remains outside of (i.e., external to) the respective aperture 102 with which it is aligned through out the life of the electromechanical bond.

Attention is now directed to FIG. 1B, which depicts an isometric-like view of an assemblage 116 resulting from the sequence depicted in FIG. 1A above. Each of the entities 108 is depicted in a face-up orientation. The material 100 is side S1 up. The entire assemblage 116 is therefore turned over or “flipped” one-hundred eighty degrees with respect to the orientation depicted in FIG. 1A. Each of the electronic entities 108 is defined by a photovoltaic cell having a solderable surface feature 118 defined on the face side.

Reference is made now to FIG. 1C, which depicts an isometric-like view of a sequence for continuing toward the discrete electronic devices 136. The assemblage 116 as described above underlies other elements to be added thereto as described below.

FIG. 1C includes a sheet of compliant, electrically non-conductive material 120 that is to be brought into contact with side S1 of the material 100. The material 120 can be formed from compliant foam or other suitable materials. In one example, material 120 is formed from or includes polyethylene naphthalate (PEN), being 0.002 inches thick. Other materials can also be used. The material 120 is defined by rows of perforations 122 that are aligned (or coincident) with the perforations 104 of the material 100.

A sheet of conductive material (material) 124 is also included. The material 124 can be defined by any suitable, solder-bondable material such as, for non-limiting example, copper, silver, brass, tin, and so on. Additionally, materials plated in solder-bondable materials such as gold or others can also be used. In one example, the material 124 is defined by copper sheet metal having a uniform thickness “T2” in the range of about 0.002 to 0.005 inches. Other materials, having other respective dimensions and form factors (e.g., plates, sheets, ribbons, blocks, and so on), can also be used. The material 124 is defined by a first side surface “S3” and a second, opposite side surface “S4”.

The material 124 defines a plurality of through apertures (apertures) 126. That is, a plurality of apertures 126 has been formed through the material 124 by way of, without limitation, machine milling, machine punching, laser cutting, water-jet cutting, or other suitable means. Each aperture 126 is defined by a rectangular plan form having a length dimension “L2” and a width dimension “W2”.

The material 124 also includes respective rows of perforations or “slits” 128 formed therein such that a plurality conjoined strips 130 of the material 124 is defined. The material 124 is considered a singular entity by virtue of the intact state of the perforations 128. The perforations 128 can be formed or defined by, without limitation, laser ablation, water-jet cutting, slicing, and so on. Other suitable formation techniques can also be used. In one example, the rows of perforations 128 are of the same parallel orientation and spacing as that of the perforations 104, such that the strips 130 are of the same size and aspect as the strips 106. Other configurations can also be used.

A quantity of solder paste 132 is introduced or provided into each of the apertures 126. Additionally, each quantity of solder paste 132 is supported in place despite the force of gravity by way of surface tension. Thus, each quantity of solder paste 132 can be supported by contact with inner side walls of the associated through aperture 126 and does not require contact with another solid entity or surface. In one example, the solder paste 132 is defined by Bi58/Sn42 solder paste having a melting temperature of about one-hundred thirty-eight degrees Celsius, as available from Indium Corporation, Clinton, N.Y., U.S.A. Other suitable solder paste 132 can also be used, as can apertures 126 having other respective dimensions such that the solder paste 132 is not supportable by surface tension alone.

The material 120 is brought into contact with side S1 of the material 100. In turn, the material 124 is brought into contact with the respective electronic entities 108 such that each aperture 126, having a respective quantity of solder paste 132 therein, is aligned with a respective one of the solderable surface features 118. Each of the conjoined strips 130 is now in spaced, parallel, overlying relationship with a corresponding one of the conjoined strips 106. The “hot bar” 114 is brought into contact with the side S3 of the material 124, coincident with the apertures 126. The quantities of solder paste 132 are melted and reflow into wetted contact with the respective solderable surface features 118. The hot bar 114 is then drawn away, allowing the quantities of solder paste 132 to cool and solidify. In another example, the solder paste 132 begins or is allowed to cool during hot bar contact in accordance with a controlled temperature rate there of. Each of the entities 108 is thus electromechanically bonded to a corresponding one of the conjoined strips 130 of the material 124.

Attention is now directed to FIG. 1D, which depicts an isometric-like view of an assemblage 134 resulting from the sequence depicted in FIGS. 1A-1C above. Each of the entities 108 is depicted in a face-up orientation. The respective materials 100 and 124 are electromechanically bonded to the electronic entities 108. The assemblage 134 is considered a singular entity including four conjoined electronic devices 136 each having a respective one of the electronic entities 108.

Reference is now directed to FIG. 1E, which depicts an isometric-like view of a singulation of an electronic device 136. Specifically, one of the electronic devices 136 is separated apart from the other three conjoined electronic devices 136. Such singulation is performed by way of severing the corresponding perforations 104, 122 and 128 such that a distinct (i.e., discrete) electronic device 136 is defined. Such singulation can also be performed to separate all of the electronic devices 136 so as to define four distinct units. The assemblage 134 is therefore disarticulated along the rows of perforations 104, 122 and 128 so that a plurality of discrete electronic devices 136 is defined.

The sequence of FIGS. 1A-1E depicts the formation of four distinct electronic devices 136 in the interest of clarity. However, it is to be understood that any suitable number of such distinct electronic devices (hundreds, thousands, and so on) can be formed in accordance with the present teachings. Furthermore, roll-to-roll, sheet-stamping, and other manufacturing techniques can be used such that pluralities of distinct electronic devices are formed or defined in a mass-production manner according to the present teachings.

### Second Illustrative Formation

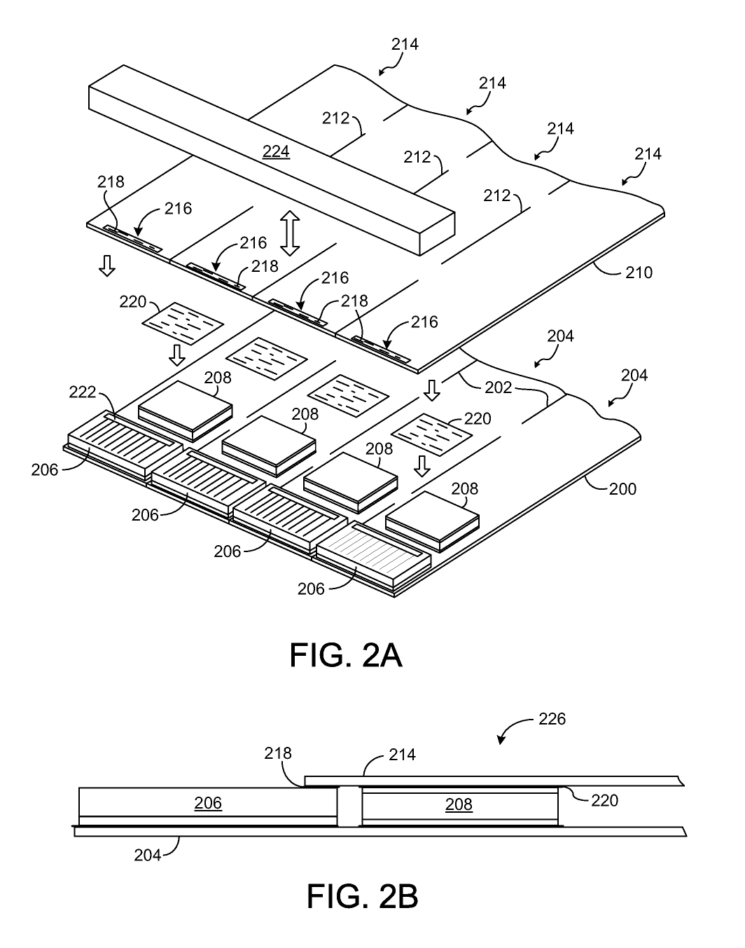

Reference is now directed to FIGS. 2A-2B, which collectively depict a sequence for forming discrete electronic devices 226. The sequence and the resulting electronic devices 226 is/are illustrative and non-limiting with respect to the present teachings. Thus, other apparatuses, devices can be configured and/or formed in accordance with the present teachings.

FIG. 2A depicts a sheet (or ribbon) of conductive material 200, which can be defined by copper, silver, gold, brass, tin, and so on. The material 200 has rows of perforations 202 formed or defined therein as described above such that conjoined strips 204 are defined. Each of the strips 204 includes a first electronic entity 206 and a second electronic entity 208 electromechanically bonded thereto in accordance with the techniques described above. In one example, each first entity 206 is defined by a multi-layer photovoltaic cell and each second entity 208 is defined by a diode. Other entity types, combinations or configurations can also be used.

A sheet of conductive material (material) 210 is also included. The material 210 can be defined by any suitable, solder-bondable material such those described above. The material 210 has rows of perforations 212 formed or defined therein as described above such that conjoined strips 214 are defined. The material 210 also includes or defines through apertures 216, each having a quantity of solder paste 218 therein suspended by way of surface tension. Additionally, respective quantities of solder paste 220 are disposed in overlying alignment with respective ones of the second entities 208.

The quantities of solder paste 220 are brought into contact with the corresponding second entity 208 there under. The material 210 is then brought into contact with the first entities 206 and the quantities of solder paste 220, such that each of the conjoined strips 214 is in overlying alignment with a corresponding conjoined strip 204. Each of the apertures 216 is in alignment with a solderable surface feature 222 of a respective one of the first entities 206.

A “hot bar” 224 is brought into contact with the material 210, coincident with the apertures 216 and the quantities of solder paste 220. The respective quantities of solder paste 218 and 220 are melted and reflow into wetted contact with the solderable surface features 222 and the second entities 208, respectively. The hot bar 224 is then drawn away, allowing the quantities of solder paste 218 and 220 to cool and solidify. In another example, the solder paste 218 and/or 220 begins or is allowed to cool during hot bar contact in accordance with a controlled temperature rate there of. Each of the first and second entities 206 and 208 is thus electromechanically bonded to a corresponding one of the conjoined strips 214 of the material 210.

Attention is now turned to FIG. 2B, which depicts a side elevation of a discrete electronic device 226 formed in accordance with FIG. 2A. The discrete (i.e., distinct) electronic device 226 includes a first electronic entity (e.g., photovoltaic cell) 206 that is electromechanically bonded to an electrically conductive strip 204 and an electrically conductive strip 214. The electronic device 226 also includes a second electronic entity (e.g., diode) 208 that is electromechanically bonded to the strip 204 and the strip 214.

The discrete electronic device 226 has been separated or singulated from other like electronic devices formed in accordance with the sequence of FIG. 2A. The distinct electronic device 226 thus includes a first entity 206 and a second entity 208 electrically coupled in parallel-circuit relationship to each other. FIGS. 2A-2B depicts the formation of four distinct electronic devices (i.e., 226) each having two electronic entities (i.e., 206 and 208) in the interest of clarity. However, the present teachings contemplate the formation of any number of discrete electronic devices in a mass-production manner, each having any suitable number of electronic entities.

### First Illustrative Method

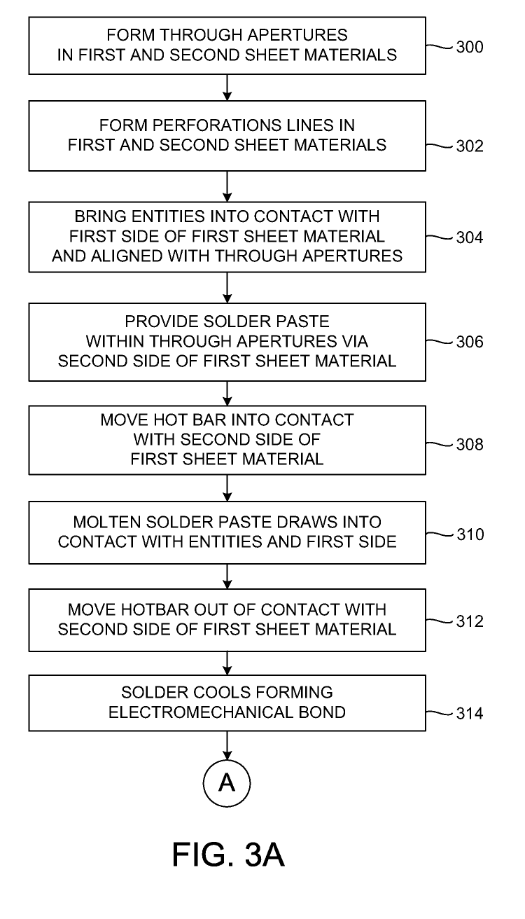

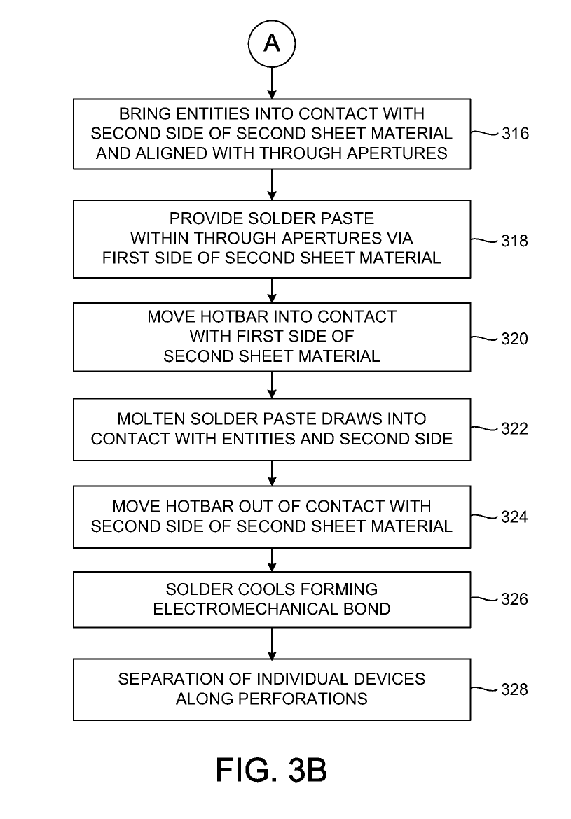

Attention is now directed to FIGS. 3A and 3B, which collectively depicts a flow diagram of a method according to another embodiment according to the present teachings. The method of FIGS. 3A-3B includes particular operations and order of execution. However, other methods including other operations, omitting one or more of the depicted operations, and/or proceeding in other orders of execution can also be used according to the present teachings. Thus, the method of FIG. 3 is illustrative and non-limiting in nature. Reference is also made to FIGS. 1A-1E in the interest of understanding the method of FIGS. 3A-3B.

At 300, through apertures are formed in first and second sheet materials. For purposes of illustration, it is assumed that a sheet of copper metal 100 is cut by laser so as to define respective through apertures 102. In turn, a sheet of copper metal 124 is cut by laser so as to define respective through apertures 126.

At 302, perforation lines are formed in the first and second sheet materials. For purposes of the present illustration, rows of perforations 104 are cut in the copper sheet 100 and rows of perforations 128 are cut in the copper sheet 124, respectively, by laser. Conjoined strips 106 are thus defined in the copper sheet 100, and conjoined strips 130 are thus defined in the copper sheet 124.

At 304, entities are brought into contact with a first side of the first sheet material and aligned with through apertures. For purposes of the present illustration, respective electronic entities 108 are brought into contact with a first side S1 of the copper sheet 100. Each of the electronic entities 108 is aligned in overlapping relationship with a respective one of the through apertures 102. For purposes of non-limiting example, each of the electronic entities 108 is defined by photovoltaic cell.

At 306, solder paste is provided within the through aperture by way of the second side of the first sheet material. For purposes of the present illustration, respective quantities of solder paste 112 are disposed within each of the apertures 102 by way of the second side S2 of the copper sheet 100. Each of the solder paste 112 quantities (or portions) is held in place by supportive contact with a solderable surface feature 110 of the corresponding entity 108.

At 308, a hot bar is moved into contact with the second side of the first sheet material. For purposes of the present illustration, a hot bar 114 is moved into contact with the copper sheet 100 in overlapping alignment (or coincidence) with the through apertures 102. The respective quantities of solder paste 112 are melted by way of the hot bar 114.

At 310, molten solder paste is drawn into contact with the electronic entities and the first side of the first sheet material. For purposes of the present illustration, the solder paste 112 with each aperture 102 melts and reflows by capillary action into wetted contact with the corresponding solderable surface feature 110 and the first side S1 of the copper sheet 100.

At 312, the hot bar is moved out of contact with the second side of the first sheet material. For purposes of the present illustration, the hot bar 114 is drawn away and out of contact with the second side S2 of the copper sheet 100.

At 314, the solder paste portions cool forming electromechanical bonds. For purposes of the present illustration, the quantities of solder paste 112 cool and solidify in place so as to electromechanically bond the respective electronic entities 108 to the copper sheet 100. In particular, each entity 108 is electrically and mechanically bonded in overlapping relationship with, and external to, a corresponding one of the through apertures 102. In another example, the solder paste 112 begins or is allowed to cool during hot bar contact in accordance with temperature rate control of the hot bar 114.

At 316, the entities are brought into contact with a second side of the second sheet material and aligned with the through apertures. For purposes of the present illustration, the respective electronic entities 108 are brought into contact with a second side S4 of the copper sheet 124. Each of the electronic entities 108 includes a solderable surface feature 118 that is aligned in overlapping relationship with a respective one of the through apertures 126.

At 318, solder paste is provided within the through apertures by way of the first side of the second sheet material. For purposes of the present illustration, respective quantities of solder paste 132 are disposed within each of the apertures 126 by way of a first side S3 of the copper sheet 124.

At 320, the hot bar is moved into contact with the first side of the second sheet material. For purposes of the present illustration, the hot bar 114 is moved into contact with the copper sheet 124 in overlapping alignment (or coincidence) with the through apertures 126. The respective quantities of solder paste 132 are melted by way of the hot bar 114.

At 322, molten solder paste is drawn into contact with the electronic entities and the second side of the second sheet material. For purposes of the present illustration, the solder paste 132 with each aperture 126 melts and reflows by capillary action into wetted contact with the corresponding solderable surface feature 118 and the second side S4 of the copper sheet 124.

At 324, the hot bar is moved out of contact with the first side of the second sheet material. For purposes of the present illustration, the hot bar 114 is drawn away and out of contact with the first side S3 of the copper sheet 124.

At 326, the solder paste portions cool forming electromechanical bonds. For purposes of the present illustration, the quantities of solder paste 132 cool and solidify in place so as to electromechanically bond the respective electronic entities 108 to the copper sheet 124. In particular, each entity 108 is electrically and mechanically bonded in overlapping relationship with and external to a respective one of the through apertures 126. Each of the electronic entities 108 is now bonded in electrically conductive relationship with one of the conjoined strips 106 and one of the conjoined strips 130. In another example, the solder paste 132 begins or is allowed to cool during contact by the hot bar 114 in accordance with a controlled temperature rate there of.

At 328, individual electronic devices are separated by way of the perforations. For purposes of the present illustration, a plurality of distinct (i.e., discrete) electronic devices 136 are defined by severing the respective rows of perforations 104 and 128. Each of the distinct electronic devices 136 includes a single electronic entity (e.g., a photovoltaic cell) 108 that is electromechanically bonded to a strip 106 of the copper sheet 100 and a strip 130 of the copper sheet 124. The distinct electronic devices 136 can be used to construct a circuit, device or system accordingly such as a photovoltaic solar panel, and so on.

In general, and without limitation, the present teachings contemplate the mass-production of distinct electronic devices. A metallic or other solder-bondable sheet (or tape or ribbon) material is laser cut, machined or otherwise processed so as to define one or more through apertures in selected locations. Copper sheet metal, having a thickness in the range of about 0.002 to 0.005 inches, is only one of numerous suitable examples of such a material according to the present teachings. The sheet material then defines a supportive and electrically conductive stratum ready to have various entities bonded thereto.

The through apertures can respectively vary in volumetric dimensions and cross-sectional profiles such that, in some examples, a solder paste can be supported within a through aperture via surface tension alone. In other examples, mechanical support is provided to a solder paste by way of contact with an entity to be bonded to the sheet material. A quantity of solder paste is provided into each of the through apertures and is supported in place by way of surface tension or by contact with an entity. In yet other examples, solder paste or portions of solder is disposed in contact with an entity and the sheet material it is to be bonded to.

Rows of perforations are formed or cut across the sheet material such that conjoined strips of the sheet material are defined. The perforations are such as to maintain continuity of the sheet material (or ribbon) at this procedural step. In some examples, the sheet material having the through apertures and rows of perforations can be handled by reel-to-reel processing machinery and the like. Other processing or handling techniques can also be used.

One or more entities are placed in contact with the sheet material, aligned with and overlapping peripheral areas of respective ones of the through apertures. Each of the entities can be defined by various electronic devices or metallic components such as, without limitation, photovoltaic cells, power semiconductors, integrated circuits, passive electrical components, and so on. Each entity includes a solderable surface feature or features that is/are in contact with the sheet material. It is noted that the entities do not require any sort of extensions, lead-wires or other protrusions in order to be soldered to the sheet material, and as such do not require penetration into any portion of the respective aperture or apertures.

A hot bar is then used to heat the sheet material and to cause the respective quantities of solder paste to assume a molten state. Hot air jets, lasers, infrared lamps, induction heaters or other devices can also be used instead of, or in addition to, the hot bar. The respective quantities of molten solder paste are then drawn by capillary action into wetted contact with the sheet material and the respective entities. Such heating is typically performed in accordance with time-and-temperature profile information provided by a vendor of the particular solder paste being used.

The hot bar (or other suitable source of heat) is then either drawn away from the sheet material, or automatically controlled while in contact with the sheet material, so as to allow the arrangement to cool. The quantities of solder paste solidify so as to form electrically-conductive, mechanically-fixed bonds between the sheet material and the respective entities.

It is further noted that bonding operations according to the present teachings use minimized quantities of solder paste and avoid unwanted or detrimental molten solder migration over known techniques. As such, the respective entities are now electromechanically bonded to respective ones of the conjoined strips of the sheet material. The above can be generally repeated so that each entity is electromechanically bonded to another conjoined strip of a second sheet (or ribbon) material distinct and spaced apart from the first sheet material.

The respective rows of perforations are then severed such that a plurality of distinct electronic devices is defined. Each electronic device includes one or more electronic entities (e.g., photovoltaic cells, semiconductors, and so on) electromechanically bonded to one or more respective, electrically-conductive strips of material. The resulting distinct electronic devices can then be used to define various electronic circuits, devices, systems and so on.

The present teachings contemplate the use of solders that include various metals having relatively low melting temperatures. However, the present teachings further contemplate that electrically conductive adhesives or other materials may exist or may be developed in the future having at least some solder-like characteristics. That is, such materials could be made to reflow at some greater temperature and then solidify (or substantially so) at some lesser temperature resulting in an electrically conductive and mechanically fixed bond. As used herein, the terms “solder”, “solder paste” and their respective analogues are intended to include other existing or future materials suitable for use according to the present teachings.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A method, comprising:
forming parallel rows of perforations in an electrically conductive material such that a plurality of conjoined strips of the material is defined;
forming an aperture through each of the conjoined strips of the material;
providing a solder paste within each of the apertures;
disposing a respective entity in overlapping contacting relationship with each of the apertures; and
electromechanically bonding the entities to the respective conjoined strips of the material by way of the solder paste.

2. The method according to claim 1, the electrically conductive material defining a first material, the method further comprising:
forming parallel rows of perforations in an electrically conductive second material such that a plurality of conjoined strips of the second material are defined;
forming an aperture through each of the conjoined strips of the second material;
providing a solder paste within each of the apertures of the second material;
disposing each of the entities in overlapping contacting relationship with a respective one of the apertures in the second material; and
electromechanically bonding the entities to the respective conjoined strips of the second material by way of the solder paste.

3. The method according to claim 2, the first material and the second material being of the same metallic constituency.

4. The method according to claim 2, the providing the solder paste within each of the apertures of the second material including supporting the solder paste by way of surface tension.

5. The method according to claim 2 further comprising separating each of the entities by way of the respective rows of perforations in the first and second materials such that a plurality of discrete devices is defined.

6. The method according to claim 1, the providing the solder paste within each of the apertures including supporting the solder paste within each aperture by way of supportive contact with the corresponding entity.

7. The method according to claim 1, the entity being defined by an electronic device having a solderable surface feature, the solderable surface feature configured to remain external to the aperture during a life of the electromechanical bond.

8. The method according to claim 1, each of the entities defining a respective first entity, the method further comprising:
electromechanically bonding a respective second entity to each of the conjoined strips of the material by way of a corresponding solder paste.

9. The method according to claim 1, the electromechanically bonding performed by bringing a heated bar into temporary contact with the strips of the material.

10. A method of forming electronic devices, comprising:
forming one or more perforation lines across a sheet of conductive material so as to define a plurality of conjoined strips;
bonding one or more electronic entities to each of the conjoined strips by way of soldering; and
separating the conjoined strips by way of the perforation lines to define a plurality of discrete electronic devices.

11. The method according to claim 10, the sheet of conductive material defining a first sheet of conductive material having a plurality of first conjoined strips, the method further comprising:
forming one or more perforation lines across a second sheet of conductive material so as to define a plurality of second conjoined strips;
bonding each of the second conjoined strips to the electronic entities of a respective one of the first conjoined strips by way of soldering; and
separating the first conjoined strips and the second conjoined strips by way of the respective perforation lines to define a plurality of discrete electronic devices.

12. The method according to claim 10 further comprising:
forming an aperture through the sheet of conductive material;
disposing a solder paste within the aperture; and
bonding one of the electronic entities to the corresponding conjoined strip by way of reflowing the solder paste.

13. The method according to claim 12, the solder paste being supported within the aperture by way of surface tension prior to the reflowing.

14. The method according to claim 10, each of the discrete electronic devices including at least a photovoltaic cell, or a diode.

15. An apparatus, comprising:
A plurality of like electronic devices each including one or more electronic entities, each electronic device also including at least one electrically conductive strip of material bonded to the electronic entities, each electrically conductive strip of material defined by severed perforations along at least one edge.

16. The apparatus according to claim 15, at least one of the electronic entities of each electronic device being a photovoltaic cell.
